(19) United States
(12) Patent Application Publication
(10) Pub. No.: US 2024/0355905 A1
(43) Pub. Date: Oct. 24, 2024

(54) ISOLATION OF ADJACENT STRUCTURES

(71) Applicant: Taiwan Semiconductor Manufacturing Company, Ltd., Hsinchu (TW)

(72) Inventors: Tzu-Ging Lin, Kaohsiung City (TW); Shun-Hui Yang, Taoyuan County (TW); Yun-Chen WU, Hsinchu (TW); Chun-Liang Lai, Hsinchu City (TW)

(73) Assignee: Taiwan Semiconductor Manufacturing Company, Ltd., Hsinchu (TW)

(21) Appl. No.: 18/303,822

(22) Filed: Apr. 20, 2023

(51) Int. Cl. H01L 29/66; H01L 29/06; H01L 29/423; H01L 29/775; H01L 29/786

(52) U.S. Cl. CPC H01L 29/66545; H01L 29/0653; H01L 29/0673; H01L 29/42392; H01L 29/66439; H01L 29/775; H01L 29/78696

(57) ABSTRACT

Provided are semiconductor devices with isolation structures and methods for fabricating such devices. An exemplary method includes forming an isolation layer over a semiconductor material; forming source/drain regions over the isolation layer; removing a selected gate structure, wherein removing the selected gate structure forms a trench in the semiconductor material; and forming an isolation structure in the trench.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far the demand has been met in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

Multi-gate devices have been introduced in an effort to improve gate control by increasing gate-channel coupling, reduce OFF-state current, and reduce short-channel effects (SCEs). One such multi-gate device that has been introduced is the fin field-effect transistor (FinFET). The FinFET gets its name from the fin-like structure which extends from a substrate on which it is formed, and which is used to form the FET channel. Another multi-gate device, introduced in part to address performance challenges associated with FinFETs, is the gate-all-around (GAA) transistor. GAA devices get their name from the gate structure which extends completely around the channel, providing better electrostatic control than FinFETs. FinFET devices and GAA devices are compatible with conventional complementary metal-oxide-semiconductor (CMOS) processes. Further, the three-dimensional structure of such devices allows them to be aggressively scaled while maintaining gate control and mitigating SCEs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a plan view of a layout of a multi-gate device, in accordance with some embodiments.

FIG. 2 is a flow chart illustrating a method, in accordance with some embodiments.

FIGS. 3-7 are perspective views of a multi-gate device during successive stages of fabrication, in accordance with some embodiments.

FIGS. 8-19 are cross-sectional views of the multi-gate device of FIG. 7 during successive stages of fabrication, in accordance with some embodiments.

FIGS. 20-21 are focused cross-sectional views of a portion of the multi-gate device of FIG. 18, in accordance with some embodiments.

FIG. 22 is a cross-sectional view of a multi-film isolation layer, in accordance with some embodiments.

FIGS. 23-25 are cross-sectional views of the multi-gate device of FIG. 9 during successive stages of fabrication, in accordance with some embodiments.

### DETAILED DESCRIPTION

The following disclosure provides many different embodiments, or examples, for implementing different features of the subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “over”, “overlying”, “above”, “upper”, “top”, “under”, “underlying”, “beneath”, “below”, “lower”, “bottom”, “side”, and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In certain embodiments herein, a “material layer” is a layer that includes at least 50 wt. % of the identified material, for example at least 60 wt. % of the identified material, at least 75 wt. % of the identified material, or at least 90 wt. % of the identified material, or substantially 100 wt. % of the identified material; and a layer that is a “material” includes at least 50 wt. % of the identified material, for example at least 60 wt. % of the identified material, at least 75 wt. % of the identified material, or at least 90 wt. % of the identified material, or substantially 100 wt. % of the identified material. For example, certain embodiments, each of a titanium nitride layer and a layer that is titanium nitride is a layer that is at least 50 wt. %, at least 60 wt. %, at least 75 wt. %, titanium nitride, or at least 90 wt. %, or substantially 100 wt. %, titanium nitride.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

It is also noted that this disclosure presents embodiments in the form of multi-gate transistors. Multi-gate transistors include those transistors whose gate structures are formed on at least two sides of a channel region. These multi-gate devices may include a P-type metal-oxide-semiconductor device or an N-type metal-oxide-semiconductor multi-gate device. Specific examples may be presented and referred to herein as FinFET devices, on account of their fin-like structure. Also presented herein are embodiments of a type of multi-gate transistor referred to as a gate-all-around (GAA) device. A GAA device includes any device that has its gate structure, or portion thereof, formed on four sides of a channel region (e.g., surrounding a portion of a channel region). Devices presented herein also include embodiments that have channel regions disposed in nanosheet channel(s), nanowire channel(s), bar-shaped channel(s), and/or other suitable channel configurations. Herein, the term “nanosheet channel” is intended to include nanowire channel and bar-shaped channel configurations.

Presented herein are embodiments of devices that may have one or more channel regions (e.g., nanosheets) associated with a single, contiguous gate structure. However, one of ordinary skill would recognize that the teaching can apply to a single channel (e.g., single nanosheet) or any number of channels. One of ordinary skill may recognize other examples of semiconductor devices that may benefit from aspects of the present disclosure.

As described herein, processes are performed to isolate adjacent devices. For example, vertically-extending isolation structures are formed between adjacent devices and have a relatively shallow depth to provide for reduced parasitic capacitance, as compared to vertically-extending isolation structures extending to a deeper depth. Further, laterally-extending isolation layers are formed between source/drain regions and the underlying semiconductor material. Such laterally-extending isolation layers reduce leakage current passing under the shallow vertically-extending isolation structures. As used herein, “source/drain region(s)” may refer to a source region or a drain region, individually or collectively depending on the context.

In certain embodiments, a continuous poly on diffusion edge (CPODE) process is used to provide isolation structures between adjacent devices. For purposes of this disclosure, a “diffusion edge” may be equivalently referred to as an active edge, where for example an active edge abuts adjacent active regions. Further, an active region includes a region where transistor structures are formed (e.g., including source, drain, and gate/channel structures). In some examples, active regions may be disposed between insulating regions. The CPODE process may provide an isolation structure between neighboring active regions, and thus neighboring transistors, by performing a dry etching process along an active edge (e.g., at a boundary of adjacent active regions) to form a cut region, and by filling the cut region with a dielectric, such as silicon nitride (SiN).

Before the CPODE process, the active edge may include a GAA dummy structure having a gate stack and a plurality of channels (e.g., nanosheet channels). The plurality of channels may each include a chemical oxide layer formed thereon, and high-K dielectric/metal gate layers may be formed over the chemical oxide layer and between adjacent channels of the plurality of channels. In addition, inner spacers may be disposed between adjacent channels at lateral ends of the plurality of channels. In various examples, source/drain epitaxial (epi) layers of adjacent active regions are disposed on either side of the GAA dummy structure (formed at the active edge), such that the adjacent source/drain epi layers are in contact with the inner spacers and plurality of channels of the GAA dummy structure.

In exemplary embodiments, an isolation layer is formed before the source/drain epitaxial (epi) layers are formed. As a result, each source/drain epi region is isolated from the underlying semiconductor material by respective portions of the isolation layer. With the isolation provided by the isolation layer, a vertically-extending isolation structure may be provided with a shallower depth to reduce parasitic capacitance while sufficiently reducing leakage current through the semiconductor material under the isolation structure.

Embodiments of the present disclosure offer advantages over the existing art, though it is understood that other embodiments may offer different advantages, not all advantages are necessarily discussed herein, and no particular advantage is required for all embodiments. For example, embodiments discussed herein include structures and related methods for performing a CPODE process.

In various embodiments, a GAA dummy structure may be formed at an active edge (e.g., at a boundary of adjacent active regions), as described above, with isolation layers and overlying source/drain epi layers of adjacent active regions disposed on either side of the GAA dummy structure.

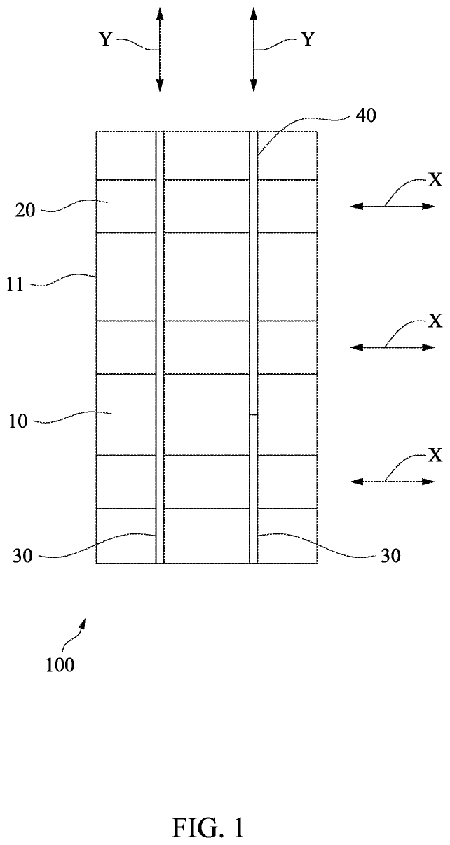

For purposes of the discussion that follows, FIG. 1 provides a simplified top-down layout view of a semiconductor device 100, such as a multi-gate device 100. In various embodiments, the multi-gate device 100 may include a FinFET device, a GAA transistor, or other type of multi-gate device. The multi-gate device 100 is formed over a substrate 10. In some embodiments, the substrate 10 may be a semiconductor substrate such as a silicon substrate. The substrate 10 may include various layers, including conductive or insulating layers formed on a semiconductor substrate. The substrate 10 may include various doping configurations depending on design requirements as is known in the art. The substrate 10 may also include other semiconductors such as germanium, silicon carbide (SiC), silicon germanium (SiGe), or diamond. Alternatively, the substrate 10 may include a compound semiconductor and/or an alloy semiconductor. Further, the substrate 10 may optionally include an epi layer, may be strained for performance enhancement, may include a silicon-on-insulator (SOI) structure, and/or have other suitable enhancement features.

FIG. 1 illustrates a unit cell 11, i.e., a portion of the semiconductor substrate 10. As shown, parallel active regions 20 are spaced apart from one another and extend in an X-direction. Further, parallel gate lines 30 are spaced apart from one another and extend in a Y-direction perpendicular to the X-direction. Exemplary gate lines 30 are formed from conductive material such as metal and form gate structures for the multi-gate device 100.

As further shown in FIG. 1, a cut region or trench is formed in one gate line 30 and is filled with isolation 40. Such isolation 40 may isolate adjacent devices from one another as described below.

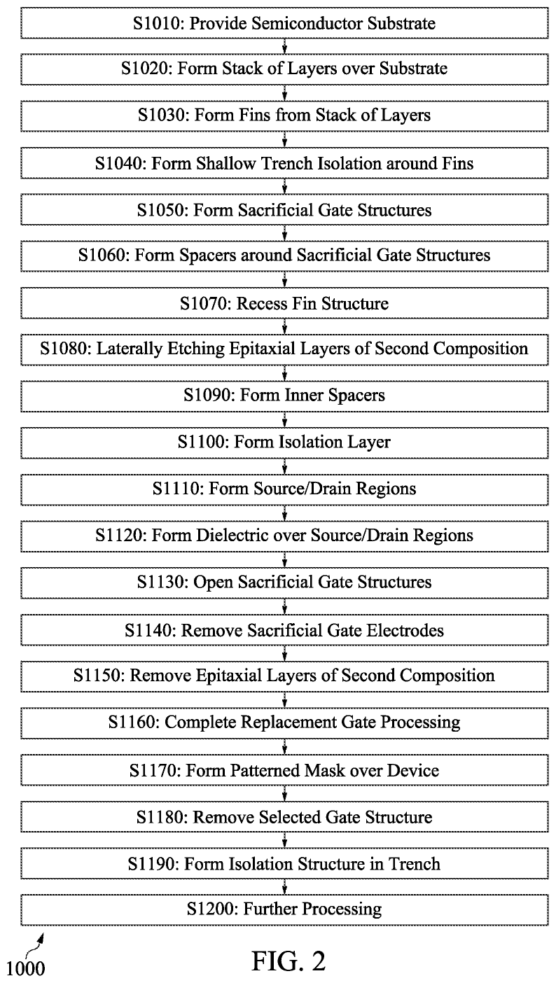

Referring to FIG. 2, illustrated therein is a method 1000 of fabrication of a semiconductor device 200 (such as a multi-gate device) using a CPODE process, in accordance with various embodiments. Method 1000 is discussed below with reference to a GAA device having a channel region that may be referred to as a nanosheet and which may include various geometries (e.g., cylindrical, bar-shaped) and dimensions. However, it will be understood that aspects of method 1000, including the disclosed CPODE process, may be equally applied to other types of multi-gate devices without departing from the scope of the present disclosure. In some embodiments, method 1000 may be used to fabricate the multi-gate device 100, described above with reference to FIG. 1. Thus, one or more aspects discussed above with reference to the multi-gate device 100 may also apply to method 1000. It is understood that method 1000 includes steps having features of a complementary metal-oxide-semiconductor (CMOS) technology process flow and thus, are only described briefly herein. Also, additional steps may be performed before, after, and/or during method 1000.

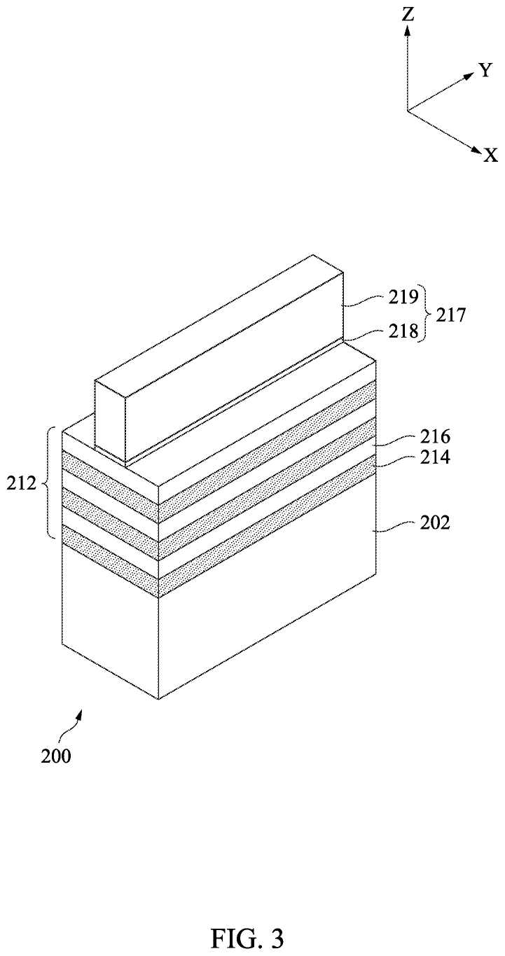

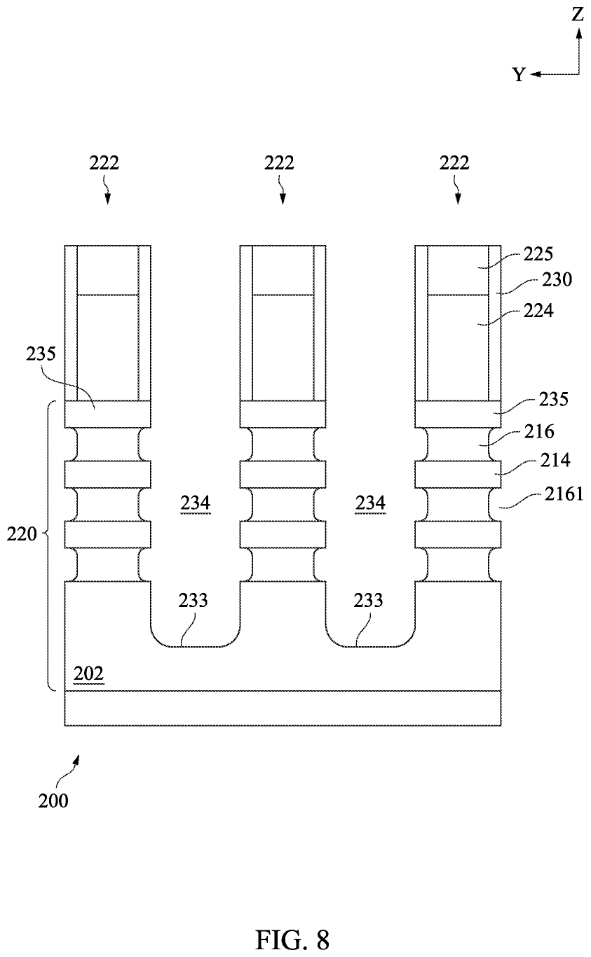

Method 1000 is described below with reference to FIGS. 3-7, which provide perspective views of the multi-gate device 200, and to FIGS. 8-______, which provide cross-sectional views of the multi-gate device 200 along a plane substantially parallel to a plane defined by an X-axis in FIG. 1, illustrating various stages of fabrication according to method 1000

Further, the semiconductor device 200 may include various other devices and features, such as other types of devices such as additional transistors, bipolar junction transistors, resistors, capacitors, inductors, diodes, fuses, static random-access memory (SRAM) and/or other logic circuits, etc., but is simplified for a better understanding of the concepts of the present disclosure. In some embodiments, the semiconductor device 200 includes a plurality of semiconductor devices (e.g., transistors), including PFETs, NFETs, etc., which may be interconnected. Moreover, it is noted that the process steps of method 1000, including any descriptions given with reference to the figures are merely exemplary and are not intended to be limiting beyond what is specifically recited in the claims that follow.

At operation S1010, the method 1000 provides a substrate 202, as shown in FIG. 3. In some embodiments, the substrate 202 may be a semiconductor substrate such as a silicon (Si) substrate. The substrate 202 may include various layers, including conductive or insulating layers formed on a semiconductor substrate. The substrate 202 may include various doping configurations depending on design requirements as is known in the art. For example, different doping profiles (e.g., p-well, n-well) may be formed on the substrate 202 in regions designed for different device types (e.g., n-type field effect transistors (NFET), p-type field effect transistors (PFET)). The suitable doping may include ion implantation of dopants and/or diffusion processes, such as boron (B) for the p-well and phosphorous (P) for the n-well. In some embodiments, the substrate 202 includes a single crystalline semiconductor layer on at least its surface portion. The substrate 202 may comprise a single crystalline semiconductor material such as, but not limited to Si, Ge, SiGe, GaAs, InSb, GaP, GaSb, InAlAs, InGaAs, GaSbP, GaAsSb and InP. Alternatively, the substrate 202 may include a compound semiconductor and/or an alloy semiconductor. In the illustrated embodiment, the substrate 202 is made of crystalline Si.

As shown in FIG. 3, at operation S1020, the method 1000 (FIG. 2) forms one or more epitaxial layers over the substrate 202. In some embodiments, an epitaxial stack 212 is formed over the substrate 202. The epitaxial stack 212 includes epitaxial layers 214 of a first composition interposed by epitaxial layers 216 of a second composition. The first and second composition may be different. Embodiments are possible including those that provide for a first composition and a second composition having different oxidation rates and/or etch selectivity. In an embodiment, the epitaxial layers 214 are SiGe and the epitaxial layers 216 are silicon. In embodiments wherein the epitaxial layer 214 includes SiGe and the epitaxial layer 216 includes silicon, the silicon oxidation rate is less than the SiGe oxidation rate. It is noted that three layers of epitaxial layers 214 and three layers of epitaxial layers 216 are illustrated in FIG. 3, which is for illustrative purposes only and not intended to be limiting beyond what is specifically recited in the claims. It can be appreciated that any number of epitaxial layers may be formed in the epitaxial stack 212; the number of layers depending on the desired number of channels regions for the GAA device 200. In some embodiments, the number of epitaxial layers 216 is between two and ten, such as six or seven.

In some embodiments, the epitaxial layer 214 has a thickness ranging from about 5 nm to about 15 nm. The epitaxial layers 214 may be substantially uniform in thickness. In some embodiments, the epitaxial layer 216 has a thickness ranging from about 5 nm to about 15 nm. In some embodiments, the epitaxial layers 216 of the stack are substantially uniform in thickness. As described in more detail below, the epitaxial layer 216 may serve as channel region(s) for a subsequently formed multi-gate device and has a thickness chosen based on device performance considerations. The epitaxial layer 214 may serve to define a gap between adjacent channel region(s) for a subsequently formed multi-gate device and has a thickness chosen based on device performance considerations.

By way of example, epitaxial growth of the epitaxial stack 212 may be performed by a molecular beam epitaxy (MBE) process, a metalorganic chemical vapor deposition (MOCVD) process, and/or other suitable epitaxial growth processes. In some embodiments, the epitaxially grown layers such as, the epitaxial layers 216 include the same material as the substrate 202. In some embodiments, the epitaxially grown layers 214 and 216 include a different material than the substrate 202. As stated above, in at least some examples, the epitaxial layer 214 includes an epitaxially grown Si₁₋ₓGeₓ layer (wherein x is from about 10 to about 55%) and the epitaxial layer 216 includes an epitaxially grown silicon (Si) layer. Alternatively, in some embodiments, either of the epitaxial layers 214 and 216 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. As discussed, the materials of the epitaxial layers 214 and 216 may be chosen based on providing differing oxidation, etch selectivity properties. In various embodiments, the epitaxial layers 214 and 216 are substantially dopant-free (i.e., having an extrinsic dopant concentration from about 0 cm⁻³ to about 1×10¹⁷ cm⁻³), where for example, no intentional doping is performed during the epitaxial growth process. In some embodiments, the bottom layer and the top layer of the epitaxial stack 212 are SiGe layers (not shown). In alternative embodiments, the bottom layer of the epitaxial stack 212 is a Si layer and the top layer of the epitaxial stack 212 is a SiGe layer (not shown).

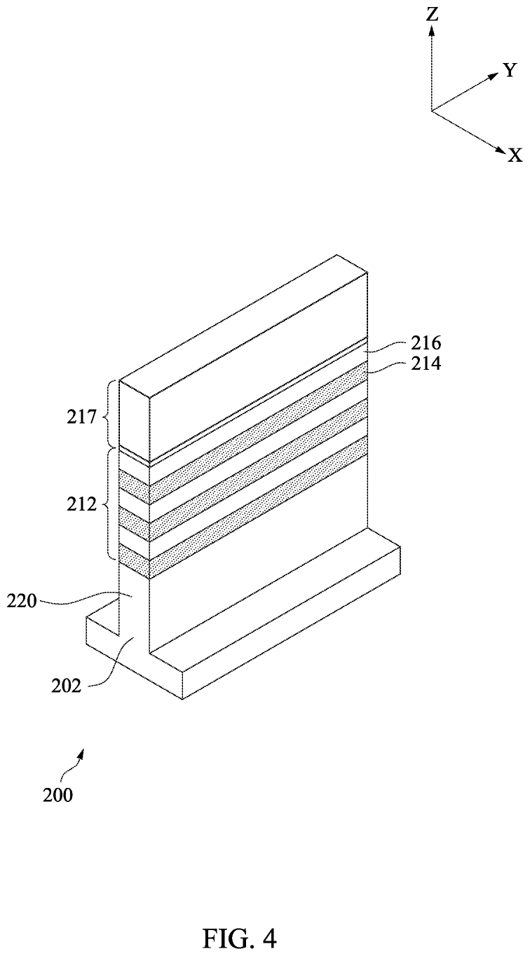

As shown in FIGS. 3-4, at operation S1030, the method 1000 (FIG. 2) patterns the epitaxial stack 212 to form a semiconductor fin 220. In some embodiments, the operation S1030 includes forming a mask layer 217 over the epitaxial stack 212, as shown in FIG. 3. The mask layer 217 includes a first mask layer 218 and a second mask layer 219. An exemplary first mask layer 218 is a pad oxide layer made of a silicon oxide, which may be formed by a thermal oxidation. An exemplary second mask layer 219 is made of a silicon nitride (SiN), which may be formed by chemical vapor deposition (CVD), including low pressure CVD (LPCVD) and plasma enhanced CVD (PECVD), physical vapor deposition (PVD), atomic layer deposition (ALD), or other suitable process. The mask layer 217 is patterned into a mask pattern by using patterning operations including photolithography and etching. Operation S1030 subsequently patterns the epitaxial stack 212 in an etching process, such as a dry etch (e.g., reactive ion etching), a wet etch, and/or other suitable process, through openings defined in the patterned mask layer 217. The stacked epitaxial layers 214 and 216 are thereby patterned into the fin 220. While FIG. 4 illustrates the formation of one fin 220, any suitable number of the fins may be formed. Trenches are etched between adjacent fins 220.

In various embodiments, each fin 220 includes an upper portion of the interleaved epitaxial layers 214 and 216, and a bottom portion that is formed from the etched substrate 202. Each fin 220 protrudes upwardly in the z-direction from the substrate 202 and extends lengthwise in the y-direction. Sidewalls of each fin 220 may be straight or inclined (not shown). In FIG. 4, additional fins would be spaced apart along the x-direction. The fins 220 may have a same width or different widths.

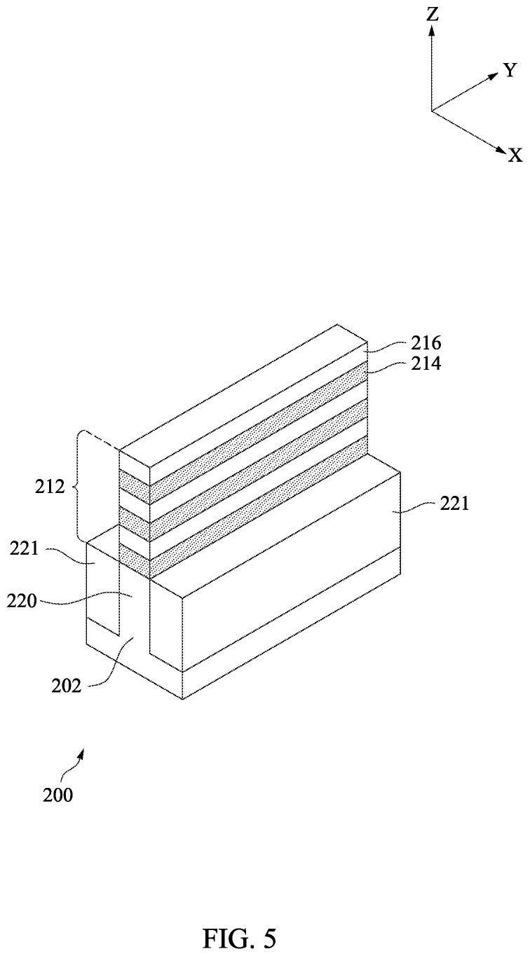

As shown in FIG. 5, at operation S1040, the method 1000 (FIG. 2) forms shallow trench isolation (STI) features (also denoted as STI features) 221 in trenches adjacent to each fin 220 with a dielectric layer. The STI features 221 may be formed by first filling the trenches around each fin 220 with a dielectric material layer to cover top surfaces and sidewalls of the fin 220 (not shown). The dielectric material layer may include one or more dielectric materials. Suitable dielectric materials for the dielectric layer may include silicon oxides, silicon nitrides, silicon carbides, fluorosilicate glass (FSG), low-K dielectric materials, and/or other suitable dielectric materials. The dielectric material may be deposited by any suitable technique including thermal growth, flowable CVD (FCVD), HDP-CVD, PVD, ALD, and/or spin-on techniques. The dielectric material layer is then planarized by using, for example, chemical mechanical planarization (CMP), until top surfaces of the mask layer 217 are revealed, and the dielectric material layer is recessed to form the shallow trench isolation (STI) features (also denoted as STI features) 221, as shown in FIG. 5. In the illustrated embodiment, the STI features 221 are formed on the substrate 202. Any suitable etching technique may be used to recess the isolation features 221 including dry etching, wet etching, RIE, and/or other etching methods, and in an exemplary embodiment, an anisotropic dry etching is used to selectively remove the dielectric material of the isolation features 221 without etching the fin 220. The mask layer 217 (shown in FIG. 4) may also be removed before, during, and/or after the recessing of the isolation features 221. In some embodiments, the mask layer 217 is removed by the CMP process performed prior to the recessing of the isolation features 221. In some embodiments, the mask layer 217 is removed by an etchant used to recess the isolation features 221.

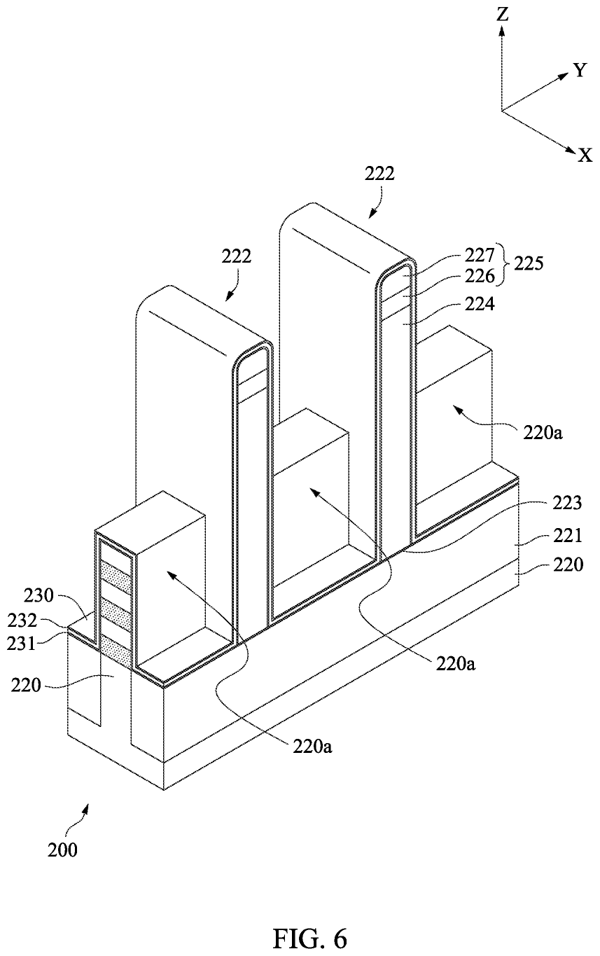

As shown in FIG. 6, at operation S1050, the method 1000 (FIG. 2) forms sacrificial (dummy) gate structures 222. The sacrificial gate structures 222 are formed over portions of the fin 220 which are to be channel regions. The sacrificial gate structures 222 may extend over a number of adjacent fins (not shown). The sacrificial gate structures 222 lie directly over and define the channel regions of the GAA devices to be formed. Each of the sacrificial gate structures 222 includes a sacrificial gate dielectric 223 and a sacrificial gate electrode 224 over the sacrificial gate dielectric 223. As shown, the gate structures 222 extend lengthwise in the x-direction and are spaced apart in the y-direction.

The sacrificial gate structures 222 are formed by first blanket depositing a sacrificial gate dielectric layer over the fin(s) 220. A sacrificial gate electrode layer is then blanket deposited on the sacrificial gate dielectric layer and over the fin(s) 220. The sacrificial gate dielectric layer includes silicon oxide, silicon nitride, or a combination thereof. The thickness of the sacrificial gate electrode layer is in a range from about 100 nm to about 200 nm in some embodiments. The sacrificial gate electrode layer 224 includes silicon such as polycrystalline silicon or amorphous silicon. The thickness of the sacrificial gate dielectric layer is in a range from about 1 nm to about 5 nm in some embodiments. In some embodiments, the sacrificial gate electrode layer is subjected to a planarization operation. The sacrificial gate dielectric layer and the sacrificial gate electrode layer are deposited using CVD, including LPCVD and PECVD, PVD, ALD, or other suitable process. A mask layer 225 is formed over the sacrificial gate electrode layer. The mask layer 225 may include a mask layer 226 such as silicon oxide and a mask layer 227 such as silicon nitride. Subsequently, a patterning operation is performed on the mask layer 225, the sacrificial gate electrode layers and the sacrificial gate dielectric layer are patterned into the sacrificial gate structures 222, including sacrificial gate dielectric layer 223 and sacrificial gate electrode 224.

As shown, the fin 220 is partially exposed between and on opposite sides of the sacrificial gate structures 222, thereby defining source/drain (S/D) regions. In this disclosure, a source and a drain are interchangeably used and the structures thereof are substantially the same.

Still referring to FIG. 6, at operation S1060, the method 1000 (FIG. 2) forms spacers 230 on sidewalls of the sacrificial gate structures 222 and sidewalls of the fins 220 by depositing spacer materials, followed by an etching. The spacers 230 may include spacer material such as silicon oxide, silicon nitride, silicon carbide, silicon oxynitride, SiCN films, silicon oxycarbide, SiOCN films, and/or combinations thereof. In some embodiments, each of the spacers 230 include multiple layers, such as a liner layer 231 and a main spacer layer 232 on a sidewall of the liner layer 231.

By way of example, the spacers 230 may be formed by depositing spacer material including a liner material layer and a dielectric material layer over the sacrificial gate structure 222 using processes such as a subatmospheric CVD (SACVD) process, a flowable CVD process, an ALD process, a PVD process, or other suitable process respectively.

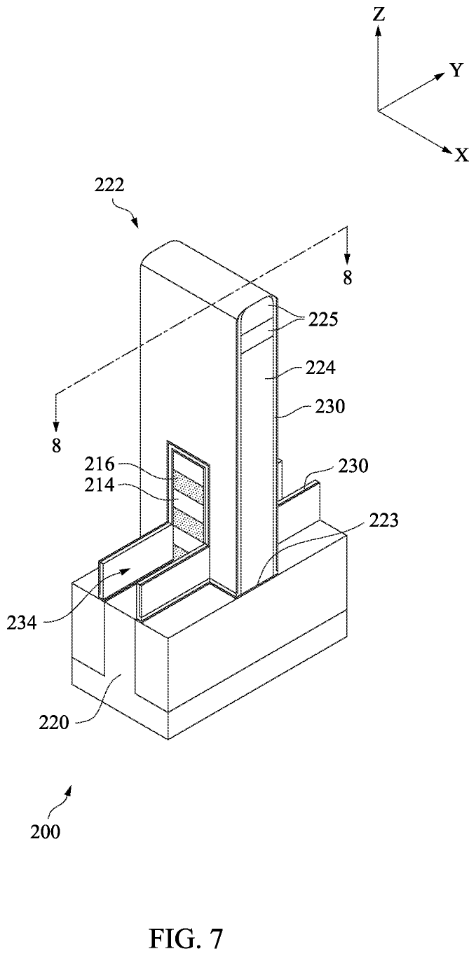

As shown in FIG. 7, the deposition of the liner material layer and the dielectric material layer are followed by, at operation S1070, etching-back (e.g., anisotropically) to expose, and remove, portions 220a of the fins 220 adjacent to and not covered by the sacrificial gate structure 222 (e.g., S/D regions). The liner material layer and the dielectric material layer may remain on the sidewalls of the sacrificial gate structure 222 as the gate sidewall spacers 230, and on the sidewalls of the fins as the fin sidewall spacers 230. In some embodiments, the etching-back process may include a wet etch process, a dry etch process, a multiple-step etch process, and/or a combination thereof. The spacers 230 may have a thickness ranging from about 5 nm to about 20 nm.

Cross-referencing FIG. 7 with FIG. 8, a cross-sectional view taken along line 8-8 in FIG. 7, at operation S1070, the method 1000 (FIG. 2) recesses the portions of the fin 220 not covered by the sacrificial gate structures 222 to form gaps or recesses 234 in the S/D regions. It is noted that FIG. 7 shows only one sacrificial gate structure 222 and the adjacent portion of fin 220 so that etching of the S/D region between the sacrificial gate structures 222 of FIG. 6 may be more clearly viewed. FIG. 8 is a cross sectional-view along line 8-8 in FIG. 7 but illustrates three sacrificial gate structures 222 and a fin 220 lying under the sacrificial gate structures 222.

As shown most clearly in FIG. 8, the stacked epitaxial layers 214 and 216 are etched to a bottom gap surface 233 formed by the fin 220. In many embodiments, the operation S1070 forms the gaps 234 by a suitable etching process, such as a dry etching process, a wet etching process, or a combination thereof. As a result of the etching process, fin segments 235 of the upper portion of the fin 220 are defined and separated from one another by the gaps 234.

As further shown in FIG. 8, method 1000 (FIG. 2) includes laterally etching the epitaxial layers 216 of the second composition at operation S1080. In an exemplary embodiment, an SiGe etchback process is removed to laterally recess the layers 216. As a result, pockets 2161 are formed laterally adjacent to the layers 216 and vertically adjacent to the layers 214.

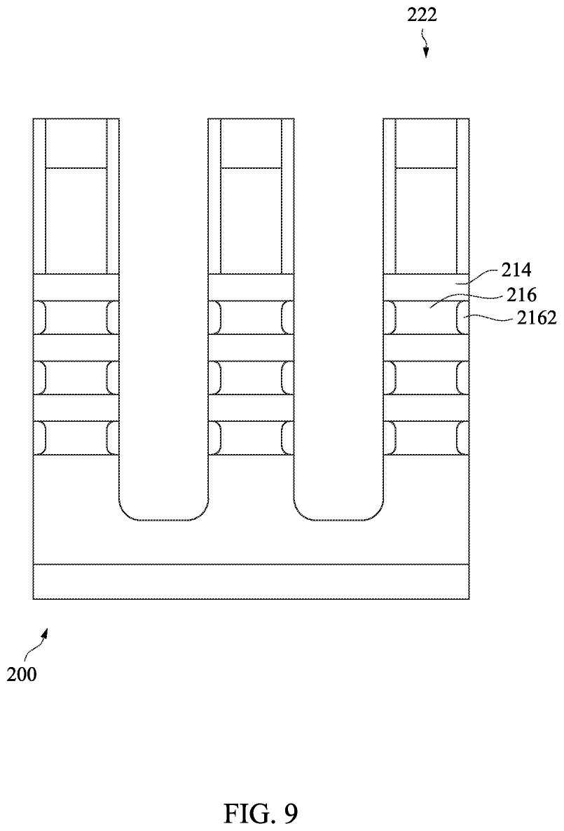

As shown in FIG. 9, method 1000 (FIG. 2) includes forming inner spacers 2162 in the pockets 2161 laterally adjacent to epitaxial layers 216 at operation S1090. In exemplary embodiments, the inner spacers 2162 may be formed from silicon oxides, silicon nitrides, silicon carbides, silicon carbide nitride, silicon oxide carbide, silicon carbide oxynitride, and/or other suitable dielectric materials. The inner spacers 2162 may be formed by ALD or any other suitable method. As shown, after deposited the material forming inner spacers 2162, the material may be trimmed from the sidewalls of epitaxial layers 214.

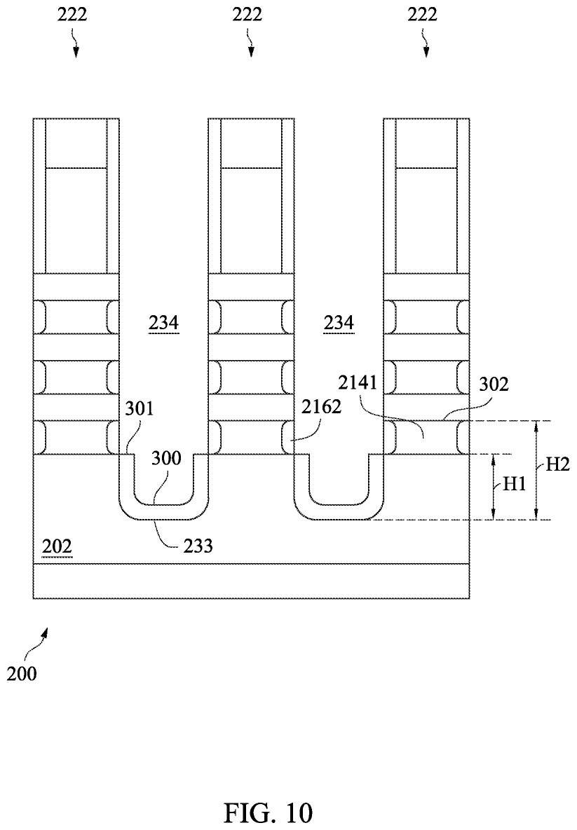

Referring to FIG. 10, method 1000 (FIG. 2) continues, at operation S1100, with forming an isolation layer 300 over the semiconductor substrate 202. Specifically, the isolation layer 300 is formed on the bottom surfaces 233 of the gaps 234. In exemplary embodiments, the isolation layer 300 is formed by an atomic layer deposition (ALD) process.

As shown, the isolation layer 300 may completely cover the bottom gap surface 233 such that no portion of the semiconductor substrate 202 between the bottom inner spacers 2162 is uncovered. Thus, each portion of the isolation layer 300 extends from one gate structure 222 to an adjacent gate structure 222.

In exemplary embodiments, the isolation layer 300 is a dielectric material with a large band gap. For example, the isolation layer 300 may be formed from a material with a band gap of at least 4 eV, such as at least 4.5 eV, at least 5 eV, at least 5.5 eV, at least 6 eV, at least 6.5 eV, at least 7 eV, at least 7.5 eV, at least 8 eV, at least 8.5 eV, or at least 8.9 eV.

In certain embodiments, the isolation layer 300 is formed from silicon nitride (SiN) and has a band gap of about 5 eV. In certain embodiments, the isolation layer 300 is formed from silicon oxide (SiO) and has a band gap of about 8.9 eV. In exemplary embodiments, the isolation layer 300 is formed from silicon oxide, silicon nitride, or a combination thereof.

In exemplary embodiments, the isolation layer includes a plurality of sublayers, such that the isolation layer is a multi-film structure. Such sublayers may be separately deposited. The thickness and order of sublayers within the multi-film structure may be designed to provide a desired band gap, a desired dielectrics constant, and to facilitate epitaxial growth of material for forming source/drain regions over the isolation layer as described below.

In exemplary embodiments, the isolation layer 300 has a small dielectrics constant (or relative permittivity). In exemplary embodiments, the isolation layer has a dielectric constant of less than 10, such as less than 7.5, less than 5, or less than 4.

In exemplary embodiments, the upper surface 301 of the isolation layer 300 is located at a height H1 over the trough or lowest point of the bottom surface 233 of the semiconductor substrate 202. In certain embodiments, the isolation layer 300 may have a vertical thickness, in the z-direction, equal to the height H1.

In exemplary embodiments, height H1 is less than 10 nanometers, such as less than 9 nm, less than 8 nm, less than 7 nm, less than 6 nm, less than 5 nm, or less than 4 nm. Height H1 may be at least 3 nm, such as at least 4 nm, at least 5 nm, at least 6 nm, at least 7 nm, at least 8 nm, or at least 9 nm.

As shown, the lowest or bottom epitaxial layer 2141 of the first composition has an uppermost or top surface 302 located at a height H2 over the trough or lowest point of the bottom surface 233 of the semiconductor substrate 202. In exemplary embodiments, the height H1 of the top surface 301 of the isolation layer 300 is less than the height H2 of the top surface 302 of the bottom epitaxial layer 2141.

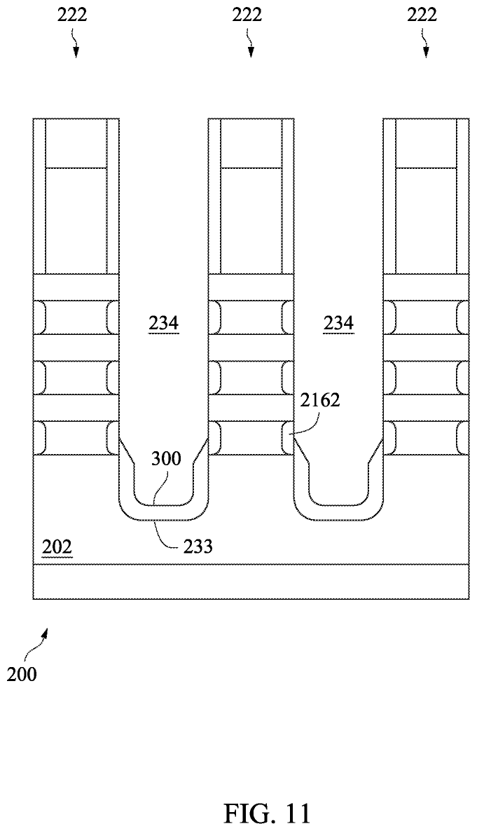

While FIGS. 9-10 describe an isolation layer 300 that is formed after forming the inner spacers 2162, it is contemplated that such layer be formed simultaneously with the inner spacers 2162. For example, FIG. 11 illustrates simultaneously forming inner spacers 2162 in the pockets 2161 laterally adjacent to epitaxial layers 216 at operation S1090 and forming an isolation layer 300 over the semiconductor substrate 202 at operation S1100. Specifically, a layer for forming the isolation layer 300 is formed on the bottom surfaces 233 of the gaps 234 and the same layer is formed in the pockets 2161 laterally adjacent to epitaxial layers 216. In exemplary embodiments, the inner spacers 2162 and isolation layer 300 is formed as a continuous layer by an atomic layer deposition (ALD) process. In exemplary embodiments, material forming the inner spacers 2162 and isolation layer 300 may be formed from silicon oxides, silicon nitrides, silicon carbides, silicon carbide nitride, silicon oxide carbide, silicon carbide oxynitride, and/or other suitable dielectric materials. As shown, after deposited the material forming layer 300 and inner spacers 2162, the material may be trimmed from the sidewalls of epitaxial layers 214.

Similar to the embodiment of FIG. 10, in FIG. 11, the isolation layer 300 may completely cover the bottom gap surface 233 such that no portion of the semiconductor substrate 202 between the bottom inner spacers 2162 is uncovered. Thus, each portion of the isolation layer 300 extends from one gate structure 222 to an adjacent gate structure 222. In exemplary embodiments, the isolation layer 300 is a dielectric material with a large band gap. For example, the isolation layer 300 may be formed from a material with a band gap of at least 4 eV, such as at least 4.5 eV, at least 5 eV, at least 5.5 eV, at least 6 eV, at least 6.5 eV, at least 7 eV, at least 7.5 eV, at least 8 eV, at least 8.5 eV, or at least 8.9 eV. In certain embodiments, the isolation layer 300 is formed from silicon nitride (SiN) and has a band gap of about 5 eV. In certain embodiments, the isolation layer 300 is formed from silicon oxide (SiO) and has a band gap of about 8.9 eV. In exemplary embodiments, the isolation layer 300 is formed from silicon oxide, silicon nitride, or a combination thereof. In exemplary embodiments, the isolation layer 300 has a small dielectrics constant (or relative permittivity). In exemplary embodiments, the isolation layer has a dielectric constant of less than 10, such as less than 7.5, less than 5, or less than 4. In exemplary embodiments, the upper surface of the isolation layer 300 is located at a height over the trough or lowest point of the bottom surface 233 of the semiconductor substrate 202 and the isolation layer 300 may have a vertical thickness, in the z-direction, equal to the height. In exemplary embodiments, the height of layer 300 is less than 10 nanometers, such as less than 9 nm, less than 8 nm, less than 7 nm, less than 6 nm, less than 5 nm, or less than 4 nm. The height of layer 300 may be at least 3 nm, such as at least 4 nm, at least 5 nm, at least 6 nm, at least 7 nm, at least 8 nm, or at least 9 nm. In exemplary embodiments, the height of the top surface of the isolation layer 300 is less than the height of the top surface of the bottom epitaxial layer.

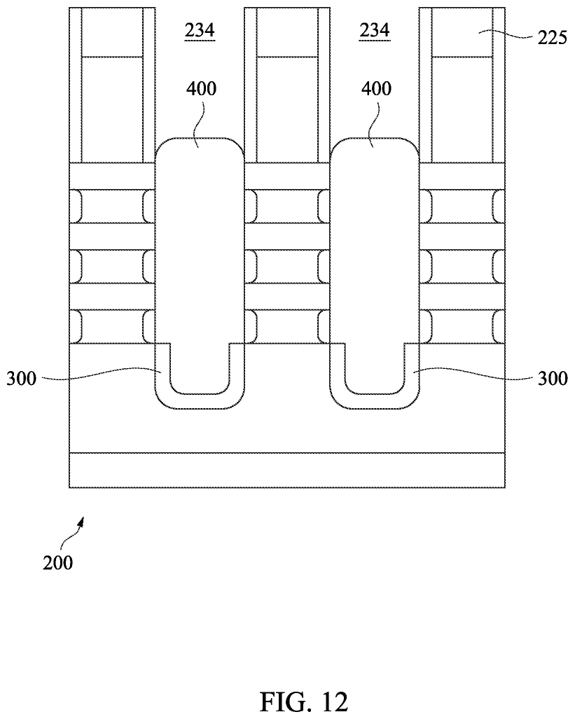

Whether forming the inner spacers 2162 and isolation layer 300 with two different deposition processes or simultaneously, the method may continue, at operation S1110, with forming source/drain regions 400, as shown in FIG. 12. In exemplary embodiments, the source/drain regions 400 are formed by epitaxial growth. For example, operation S1110 may include selectively growing epitaxial material over the isolation layer 300 to form source/drain regions 400. In exemplary embodiments, the source/drain regions 400 are strained source/drain regions 400.

The epitaxial material may include one or more layers of Si, SiP, SiC and SiCP for an n-channel FET or Si, SiGe, Ge for a p-channel FET. For the P-channel FET, boron (B) may also be contained in the source/drain. The source/drain epitaxial layers may be formed by an epitaxial growth method using CVD, ALD, or molecular beam epitaxy (MBE).

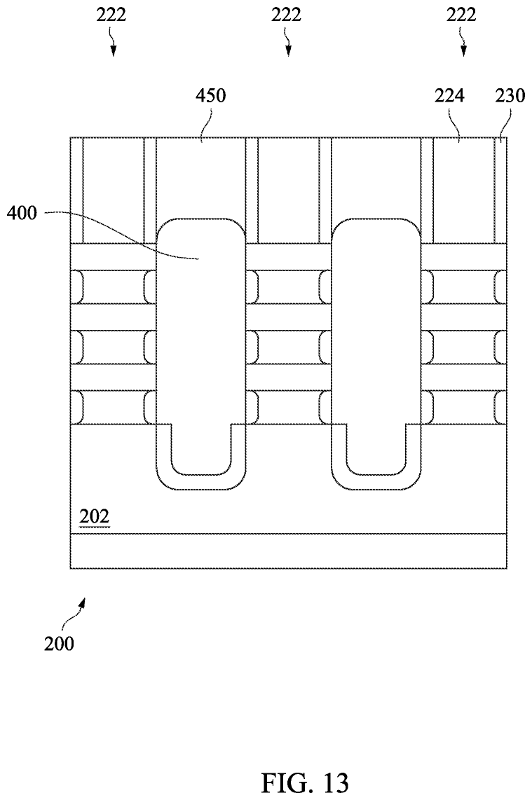

In FIG. 13, method 1000 includes, at operation S1120, forming dielectric 450 over the source/drain regions 400. Specifically, the gaps 234 are filled with dielectric 450.

As further shown in FIG. 13, method 1000 includes, at operation S1130, opening the sacrificial gate structures 222. Specifically, a chemical mechanical planarization (CMP) process may be performed to remove the mask layer 225 and to uncover the sacrificial gate electrode 224.

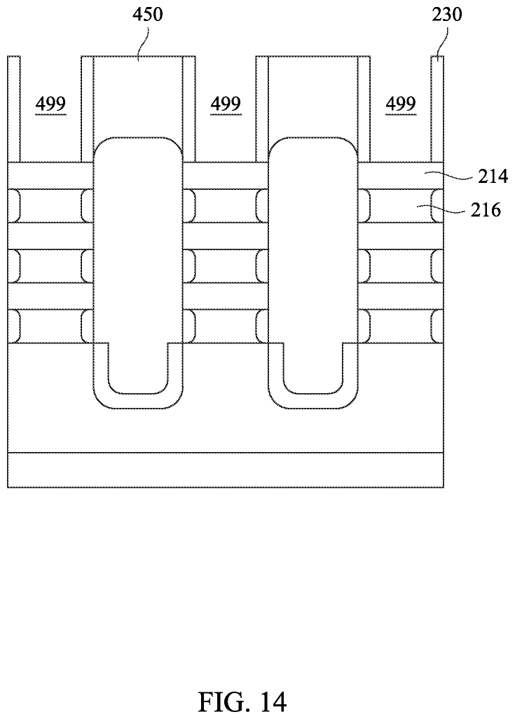

As shown in FIG. 14, method 1000 continues with removing the sacrificial gate electrode 224 to form gate cavities 499 at operation S1140. As shown, the gate cavities 499 are bounded by the sidewall spacers 230 and by the uppermost epitaxial layer 214.

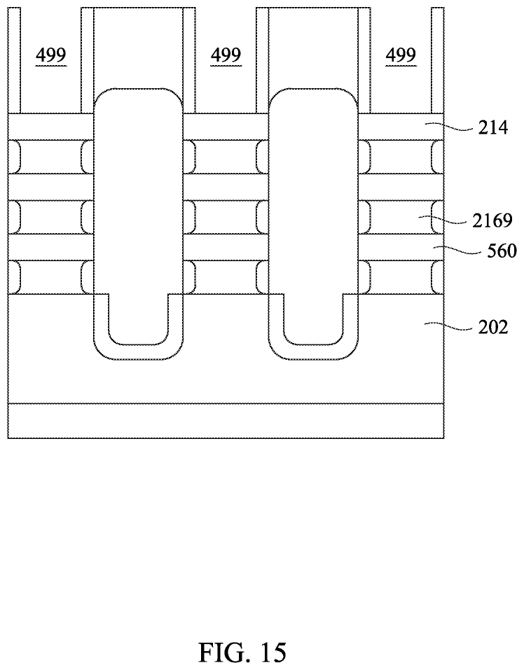

In FIG. 15, method 1000 removes the epitaxial layers 216 of the second composition at operation S1150. As a result, gaps 2169 are formed between the epitaxial layers 214 of the first composition. In this manner, the epitaxial layers 214 of the first composition are formed as vertically-spaced apart semiconductor nanosheets 560.

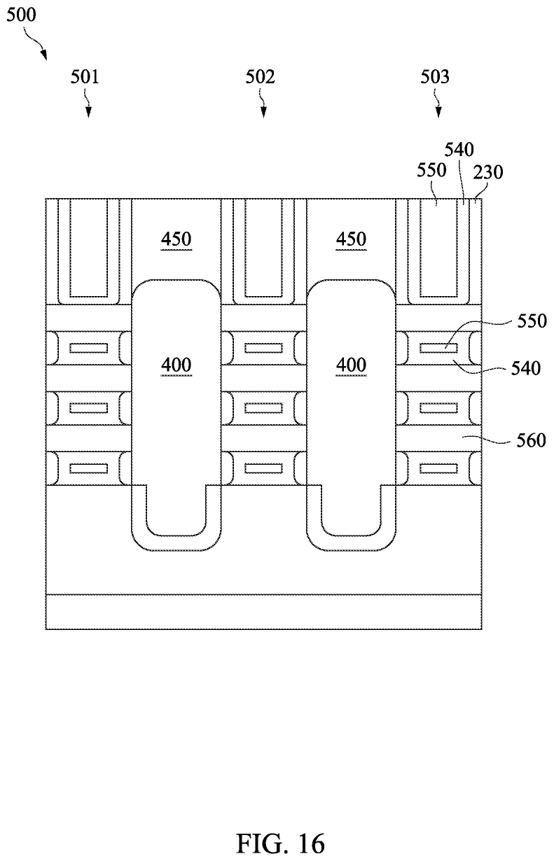

In FIG. 16, method 1000 includes, at operation S1160, completing a replacement metal gate process to form gate structures 500, such as gate structure 501, gate structure 502, and gate structure 503.

In exemplary embodiments, the replacement metal gate process includes forming a gate dielectric layer 540 in the gate cavities 499 and in the gaps 2169, and forming a gate electrode material 550 over the gate dielectric layer 540 to fill the gate cavities 499 and fill the gaps 2169.

An exemplary gate dielectric layer(s) 540 is deposited conformally in the gate cavities 499 and gaps 2169. The gate dielectric 540 may be formed on the semiconductor nanosheets 560, and the gate electrode material 550 may be formed on the gate dielectric layer(s) 540. Thus, each semiconductor nanosheet 560 is wrapped in gate dielectric 540 and surrounded by gate electrode material 550.

In accordance with some embodiments, the gate dielectric layer(s) 540 comprises silicon oxide, silicon nitride, or multilayers thereof. In some embodiments, the gate dielectric layer(s) 540 is a high-k dielectric material, and in these embodiments, the gate dielectric layer(s) 540 may have a k value greater than about 7.0, and may include a metal oxide or a silicate of Hf, Al, Zr, La, Mg, Ba, Ti, Pb, and combinations thereof. The formation methods of the gate dielectric layer(s) 540 may include Molecular-Beam Deposition (MBD), ALD, PECVD, and the like.

The gate electrode material 550 is deposited over the gate dielectric layer(s) 540 and fills the remaining portion of the gate cavity. The gate electrode material 550 may be a metal-containing material such as TiN, TaN, TaC, Co, Ru, Al, combinations thereof, or multi-layers thereof. For example, although a single gate electrode material is illustrated, any number of work function tuning layers may be deposited.

As shown, the FIG. 16, the replacement metal gate process further includes removing excess portions of the gate dielectric layer(s) 540 and the gate electrode material 550 located over the top surface of the ILD 450. For example, a planarization process, such as a CMP process, may be performed to remove the excess portions of the gate dielectric layer(s) 540 and the gate electrode material 550. The remaining portions of material of the gate dielectric layer(s) 540 and the gate electrode material 550 thus form the replacement gate structure 500 of the resulting device 200. The gate dielectric layer(s) 540 and gate electrode material 550 may be collectively referred to as a “gate,” a “gate stack,” or a “gate structure.” Each gate structure 500 may extend along sidewalls of a channel region of the fin structures.

After completing the replacement metal gate process, method 1000 may continue with forming an isolation structure to isolate adjacent devices.

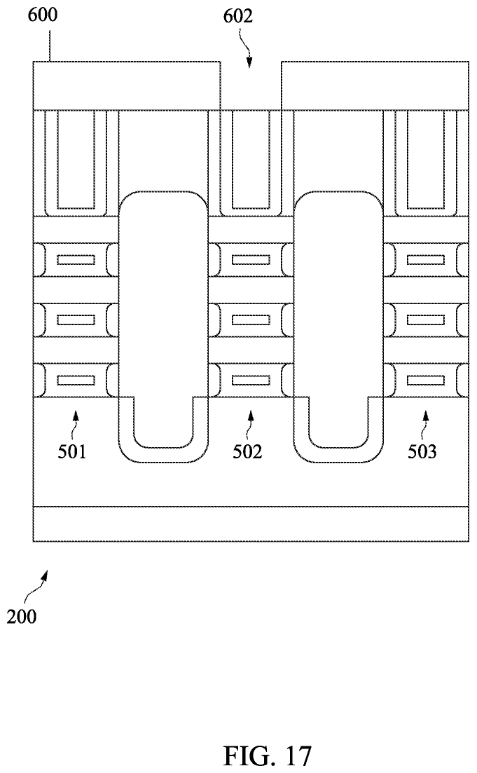

For example, in FIG. 17, method 1000 may continue with operation S1170, including forming a patterned mask covering non-selected structures. By way of example, a photolithography and etch process may be performed to form a patterned hard mask 600 lying over gate structures 501 and 503, while gate structure 502 is not covered by the patterned mask 600. Specifically, the patterned hard mask 600 defines an opening 602 overlying the gate structure 502 selected for removal.

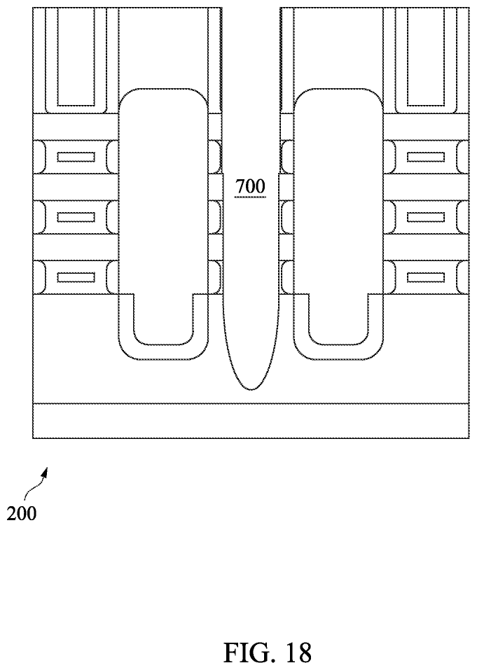

Thereafter, method 1000 includes, at operation S1180, performing a selective etch process to remove the selected gate structure 502, as shown in FIG. 18. During the etching process, the metal gate material 550, high-k gate dielectric 540, semiconductor nanosheets 560, and a portion of substrate 202 under the gate structure 502 are etched to form a trench 700 in cut metal gate regions. In various examples, the trench 700 may be etched using a dry etch (e.g., reactive ion or plasma etching).

The etching process may include an initial selective deposition of a liner (not shown) over the hard mask 600. For example, a CH₄ deposition process may be performed to selectively deposit the liner on the hard mask 600.

An exemplary etching process may be performed by any highly directional etch processes that selectively etch silicon over silicon oxide or silicon nitride.

The exemplary etching process includes Si etch steps with highly selective etchants, such as HBr based plasma, which can efficiently remove Si with minor damage to the inner spacer, which may be consist of silicon, carbon, nitrogen, and oxygen. The etch rates and selectivity can be tuned by adding O₂ or CO₂ into the HBr plasma. During the etching processes, sidewall passivation steps may be used to preserve the CD of trenches without being broadening by the Si etch steps. For example, sidewall passivation steps utilizing SiCl₄, HBr, and O₂ precursors may be used to form sidewall oxide for this purpose. Furthermore, to avoid having the etch stopped by etch by-product or oxide passivation layers, break-through steps utilizing low selective etchants, such as CF₄, may be used to remove them.

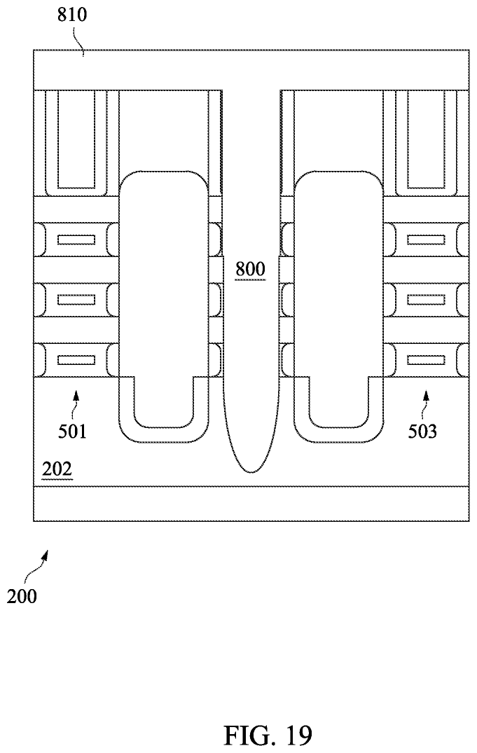

As shown in FIG. 19, method 1000 proceeds with operation S1190, including forming an isolation structure 800 in the trench 700.

In exemplary embodiments, a refill process is used to form an isolation material 800 over the structure 200. An exemplary material 800 is silicon nitride. The material 800 fills the previously formed trenches 700 and electrically isolates the now adjacent gate structures 501 and 503 from one another. In some embodiments, the material 800 includes SiN. Alternatively, in some cases, the material 800 may include SiO₂, silicon oxynitride, FSG, a low-k dielectric, combinations thereof, and/or other suitable materials known in the art. In various examples, the material 800 may be deposited by a CVD process, an SACVD process, a flowable CVD process, an ALD process, a PVD process, and/or other suitable process. In some cases, after depositing the material 800, a chemical mechanical polishing (CMP) process may be performed to remove excess material 810 and planarize a top surface of the device 200.

Method 1000 may continue at operation S1200 where further processing may be performed. Generally, the further processing may form various features and regions known in the art. For example, subsequent processing may form contact openings, contact metal, as well as various contacts/vias/lines and multilayer interconnect features (e.g., metal layers and interlayer dielectrics) over the substrate 202, configured to connect the various features to form a functional circuit that may include one or more multi-gate devices. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. Moreover, additional process steps may be implemented before, during, and after method 1000, and some process steps described above may be replaced or eliminated in accordance with various embodiments of method 1000.

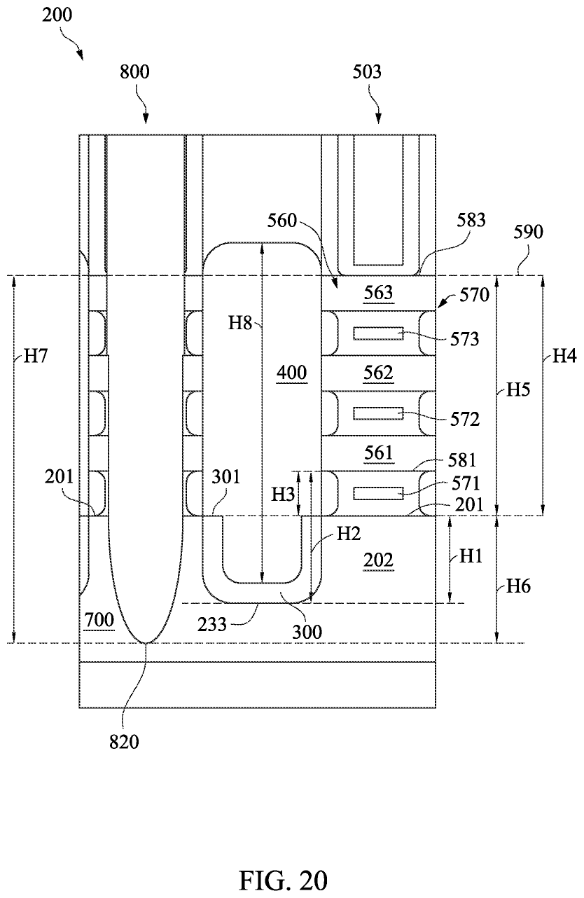

FIG. 20 is a focused view of the isolation structure 800 in trench 700 and an adjacent gate structure 503. In FIG. 20, the device 200 has been planarized to remove the excess material 810 shown in FIG. 19.

As shown, the gate structure 503 is formed with three semiconductor nanosheets 560, a bottom or lowest nanosheet 561, a middle nanosheet 562, and a top or uppermost nanosheet 563. Accordingly, the gate structure 503 includes gate portions 570 that lie under the nanosheets 561, 562, and 563, respectively, where the removed layers 214 (FIG. 14) were formerly located. Specifically, a lowest or bottom gate portion 571 lies directly under the lowest nanosheet 561 and contacts the semiconductor substrate 202 at an uppermost surface 201 of the semiconductor substrate 202; a middle gate portion 572 lies directly under the middle nanosheet 562 and directly over the lowest nanosheet 561; and an uppermost or top gate portion 573 lies directly under the uppermost nanosheet 563 and directly over the middle nanosheet 562.

As shown, the lowest gate portion 571 has an upper surface 581 located at a vertical height H3 over the uppermost surface 201 of the semiconductor substrate 202. Further, the upper surface 581 of the lowest gate portion 571 is located at a height H2 over the bottom surface 233 of the isolation layer 300. Further, the isolation layer 300 has a top surface 301 at a height H1 over the bottom surface 233. As shown height H1 is less than the vertical height H2 of the upper surface 581 of the lowest gate portion 571. Providing the upper surface 581 of the lowest gate portion 571 at a greater height than the top surface 301 of the isolation layer 300 avoids impacting the electrical conductance of the epi.

As shown, the uppermost nanosheet 563 has an upper surface 583 defining a plane 590 and located at a vertical height H4 over the uppermost surface 201 of the semiconductor substrate 202. In exemplary embodiments, the vertical height H4 is from 42 nm to 46 nm, such as from 43.4 nm to 44.9 nm, with an average of 44.2 nm.

As shown, the upper surface 583 of the uppermost nanosheet 563 and plane 590 is located at a vertical height H5 over the upper surface 301 of the isolation layer 300. In exemplary embodiments, the vertical height H5 is from 38 nm to 43 nm, such as from 39.3 nm to 41.3 nm, with an average of 40.3 nm.

In FIG. 20, the trench 700 and isolation structure 800 have a lowest point 820, or nadir 820, in the vertical or z-direction. The uppermost surface 201 of the semiconductor substrate 202 is located at a vertical height H6 over the nadir 820.

In exemplary embodiments, vertical height H4 is greater than vertical height H6. For example, vertical height H6 may be less than 95% of vertical height H4, such as less than 90% of vertical height H4, less than 85% of vertical height H4, less than 80% of vertical height H4, less than 75% of vertical height H4, less than 70% of vertical height H4, less than 65% of vertical height H4, less than 60% of vertical height H4, less than 55% of vertical height H4, or less than 50% of vertical height H4.

Further, the upper surface 583 of the uppermost nanosheet 563 is located at a vertical height H7 over the nadir 820. The vertical height H7 may be considered to be the depth of the trench 700 as measured from the upper surface 583 of the uppermost nanosheet 563.

In exemplary embodiments, the vertical height H7 may be at least 60 nanometers (nm), such as at least 62 nm, at least 64 nm, at least 66 nm, at least 68 nm, at least 70 nm, at least 71 nm, at least 72 nm, at least 74 nm, at least 76 nm, at least 78 nm, at least 80 nm, at least 82 nm, at least 84 nm, or at least 86 nm.

In exemplary embodiments, the vertical height H7 may be no more than 120 nanometers (nm), such as no more than 110 nm, no more than 100 nm, no more than 90 nm, such as no more than 88 nm, no more than 86 nm, no more than 84 nm, no more than 82 nm, no more than 80 nm, no more than 78 nm, no more than 76 nm, no more than 74 nm, no more than 72 nm, or no more than 70 nm.

As shown in FIG. 20, each source/drain region 400 is formed with a vertical height H8 extending from a bottom-most surface and an uppermost surface of the source/drain region 400. In certain exemplary embodiments, vertical height H8 is less than vertical height H7. In certain exemplary embodiments, vertical height H7 is less than vertical height H8.

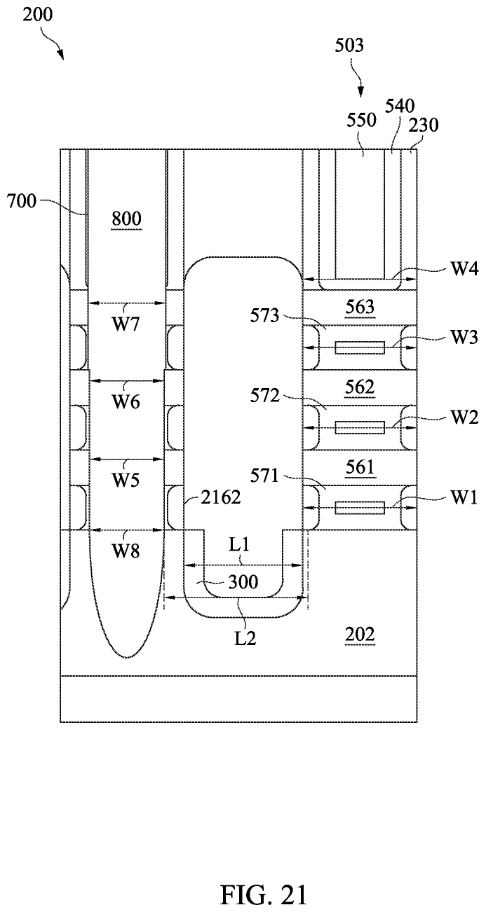

FIG. 21 is a focused view of the isolation structure 800 in trench 700 and an adjacent gate structure 503 of FIG. 19, similar to FIG. 20.

As shown in FIG. 21, the lowest or bottom gate portion 571 has a lateral width W1 in the Y-direction. In exemplary embodiments, the lateral width W1 is from 14 nm to 19 nm, such as from 14.5 nm to 17.9 nm, with an average of 16.4 nm.

As shown in FIG. 21, the middle gate portion 572 has a lateral width W2 in the Y-direction. In exemplary embodiments, the lateral width W2 is from 12 nm to 18 nm, such as from 12.8 nm to 17.0 nm, with an average of 15.1 nm.

As shown in FIG. 21, the uppermost or top gate portion 573 has a lateral width W3 in the Y-direction. In exemplary embodiments, the lateral width W3 is from 13 nm to 17 nm, such as from 14.0 nm to 16.2 nm, with an average of 15.2 nm.

As shown in FIG. 21, the gate structure 503 above the uppermost nanosheet 563 has a lateral width W4 in the Y-direction. In exemplary embodiments, the lateral width W4 is from 13 nm to 16 nm, such as from 14.2 nm to 15.0 nm, with an average of 14.6 nm.

Cross-referencing FIGS. 20 and 21, the device 200 may be formed with a gate structure 500 having a desired ratio of vertical height H4, to the lateral widths W1, W2, W3, and W4, collectively referred to as gate width GW. For example, the ratio of H4:GW may be from (43.4/17.9=2.42) to (44.9/12.8=3.51).

In certain embodiments, the ratio of H4:GW may be at least 2:1, at least 2.1:1, at least 2.2:1, at least 2.3:1, at least 2.4:1, at least 2.5:1, at least 2.6:1, at least 2.7:1, at least 2.8:1, at least 2.9:1, at least 3.1:1, at least 3.2:1, at least 3.3:1, at least 3.4:1, at least 3.5:1, at least 3.6:1, at least 3.7:1, at least 3.8:1, at least 3.9:1, or at least 4:1. In certain embodiments, the ratio of H4:GW may be at most 2:1, at most 2.1:1, at most 2.2:1, at most 2.3:1, at most 2.4:1, at most 2.5:1, at most 2.6:1, at most 2.7:1, at most 2.8:1, at most 2.9:1, at most 3.1:1, at most 3.2:1, at most 3.3:1, at most 3.4:1, at most 3.5:1, at most 3.6:1, at most 3.7:1, at most 3.8:1, at most 3.9:1, or at most 4:1.

Referring back to FIG. 21, the trench 700 and isolation structure 800 are formed with a lateral width W5 in the Y-direction at a plane defined by the lowest nanosheet 561. In exemplary embodiments, the lateral width W5 is from 16 nm to 20 nm, such as from 16.2 nm to 19.1 nm, with an average of 17.7 nm.

Also, the trench 700 and isolation structure 800 are formed with a lateral width W6 in the Y-direction at a plane defined by the middle nanosheet 562. In exemplary embodiments, the lateral width W6 is from 16 nm to 19 nm, such as from 16.6 nm to 18.3 nm, with an average of 17.5 nm.

Moreover, the trench 700 and isolation structure 800 are formed with a lateral width W7 in the Y-direction at a plane defined by the uppermost nanosheet 563. In exemplary embodiments, the lateral width W7 is from 19 nm to 22 nm, such as from 19.1 nm to 21.5 nm, with an average of 20.2 nm.

Cross-referencing FIGS. 20 and 21, the device 200 may be formed with a desired ratio of the isolation structure 800 depth or vertical height H7, to the lateral widths W5, W6, W7, and W8, collectively referred to as isolation width IW. For example, the ratio of H7:IW may be from (71.8/21.5=3.3) to (86.1/16.2=5.3). In certain embodiments, the ratio of H7:IW may be at least 2:1, at least 2.5:1, at least 2.75:1, at least 3:1, at least 3.1:1, at least 3.2:1, at least 3.3:1, at least 3.4:1, at least 3.5:1, at least 3.6:1, at least 3.7:1, at least 3.8:1, at least 3.9:1, at least 4:1, at least 4.1:1, at least 4.2:1, at least 4.3:1, at least 4.4:1, at least 4.5:1, at least 4.6:1, at least 4.7:1, at least 4.8:1, at least 4.9:1, or at least 5:1. In certain embodiments, the ratio of H7:IW may be at most 2:1, at most 2.5:1, at most 2.75:1, at most 3:1, at most 3.1:1, at most 3.2:1, at most 3.3:1, at most 3.4:1, at most 3.5:1, at most 3.6:1, at most 3.7:1, at most 3.8:1, at most 3.9:1, at most 4:1, at most 4.1:1, at most 4.2:1, at most 4.3:1, at most 4.4:1, at most 4.5:1, at most 4.6:1, at most 4.7:1, at most 4.8:1, at most 4.9:1, or at most 5:1.

As shown in FIG. 21, at the interface of the isolation layer 300 and the uppermost surface 201 of the semiconductor substrate 202, the isolation layer has a lateral length L1 in the Y-direction. Specifically, the isolation layer 300 extends between the inner spacers 2162 of the gate structure 503 and the removed gate structure 502, completely covering the surface 201 of the semiconductor substrate 202. In exemplary embodiments, the lateral length L1 is from 19 nm to 24 nm, such as from 19.9 nm to 23.3 nm, with an average of 21.4 nm.

As shown in FIG. 21, at the interface of the isolation layer 300 and the uppermost surface 201 of the semiconductor substrate 202, the trench 700 and isolation structure 800 are distanced from the conductive gate, i.e., from the high-K/metal gate stack 540/550, of the gate structure 503 by a lateral length L2 in the Y-direction. In exemplary embodiments, the lateral length L2 is from 22 nm to 34 nm, such as from 25 nm to 32 nm, such as from 26.8 nm to 30.7 nm, with an average of 28.9 nm.

In exemplary embodiments, the width W8 of the isolation structure 800 at the uppermost surface 201 of the semiconductor substrate 202 is less than the length L2.

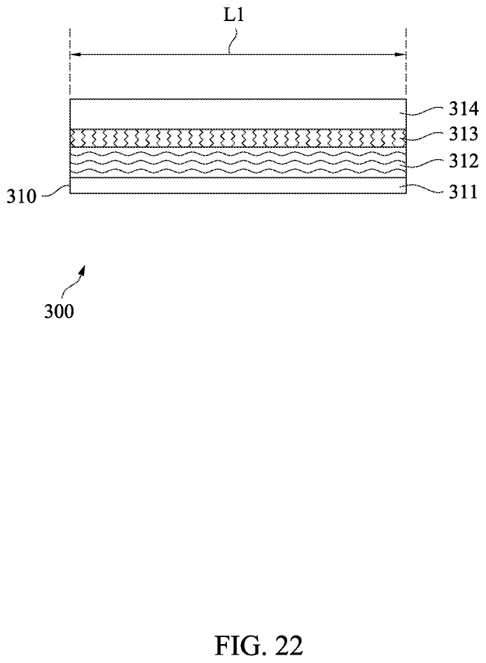

Referring to FIG. 22, a multi-film isolation layer 300 is shown. The illustrated isolation layer 300 includes four sublayers 310, including sublayers 311, 312, 313, and 314, though any suitable number may be used. As shown, the isolation layer 300 has a lateral length L1, and each sublayer 310 has a lateral length L1. The material of each sublayer 310 may be selected for a desired dielectrics constant (or relative permittivity ε). Further, the vertical thickness d of each sublayer 310 may be selected. As shown, the sublayers 310 may have different thicknesses, though it is envisioned that the sublayers may have a same thickness.

Parasitic capacitance C is calculated with the equation C=εε^{o}A/d, where ε is the relative permittivity of the material, ε^{o} is the relative permittivity of a vacuum or free space, A is the area of the layer of material, and d is the thickness of the layer of material. Thus, given a same area A, reducing ε and increasing d will result in a reduced parasitic capacitance. As may be understood, selecting thicknesses and materials of certain relative permittivity may allow for tuning the parasitic capacitance of each sublayer, and of the isolation layer 300 as a whole.

While FIGS. 9-21 contemplate a method in which the isolation layer 300 is formed on the bottom surfaces 233 of the gaps 234, in some methods an intervening layer may be form on the bottom surfaces 233 of the gaps 234.

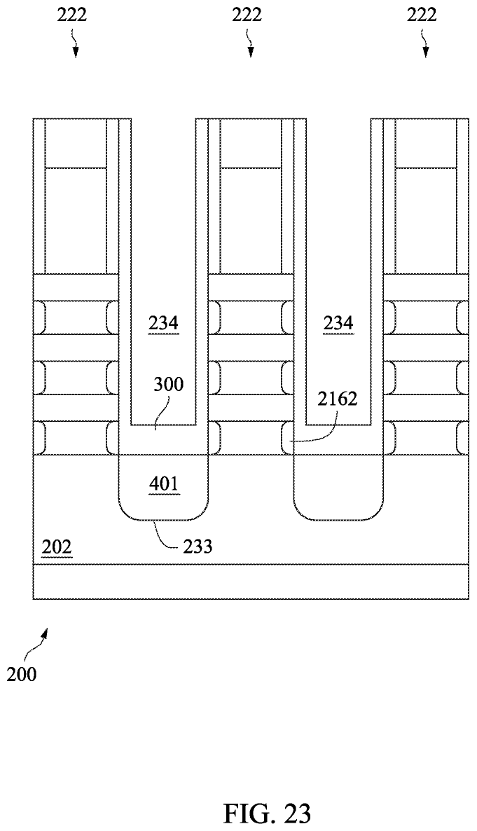

For example, referring to FIGS. 23-25, the structure of FIG. 9 is processed, such as at an operation S1095 after operation S1090, by forming epitaxial material 401 on the bottom surfaces 233 of the gaps 234. For example, operation S1095 may include selectively growing epitaxial material over the bottom gap surface 233 formed by the fin 220. In exemplary embodiments, the epitaxial material 401 may be considered be a lower portion of the later-formed source/drain regions 400. The epitaxial material may include one or more layers of Si, SiP, SiC and SiCP for an n-channel FET or Si, SiGe, Ge for a p-channel FET. For the P-channel FET, boron (B) may also be contained in the epitaxial material. The epitaxial material may be formed by an epitaxial growth method using CVD, ALD, or molecular beam epitaxy (MBE).

As shown in FIG. 23, epitaxial material 401 covers the bottom gap surface 233 formed by the fin 220 and extends between the bottom inner spacers 2162.

As shown in FIG. 23, after forming the epitaxial material 401, the method may continue, at operation S1100, with forming an isolation layer 300. Specifically, the isolation layer 300 is formed on the epitaxial material 401. In exemplary embodiments, the isolation layer 300 is formed by an atomic layer deposition (ALD) process.

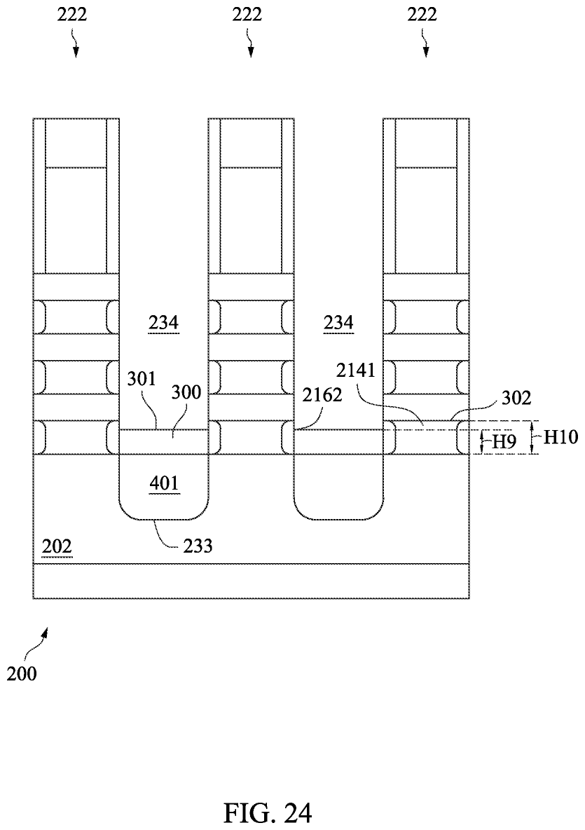

As shown in FIG. 24, forming isolation layer 300 at operation S1100 includes trimming portions of the deposited isolation layer 300 from the sidewalls of the recesses 234 and recessing the top surface 301. As shown, the isolation layer 300 may completely cover the epitaxial material 401. Specifically, the isolation layer 300 extends between the bottom inner spacers 2162.

In FIG. 24, the upper surface 301 of the isolation layer 300 is located at a height H9 over the epitaxial material 401. In certain embodiments, the isolation layer 300 may have a vertical thickness, in the z-direction, equal to the height H9.

In exemplary embodiments, height H9 is less than 10 nanometers, such as less than 9 nm, less than 8 nm, less than 7 nm, less than 6 nm, less than 5 nm, or less than 4 nm. Height H9 may be at least 3 nm, such as at least 4 nm, at least 5 nm, at least 6 nm, at least 7 nm, at least 8 nm, or at least 9 nm.

As shown, the lowest or bottom epitaxial layer 2141 of the first composition has an uppermost or top surface 302 located at a height H10 over the epitaxial material 401. In exemplary embodiments, the height H9 of the top surface 301 of the isolation layer 300 is less than the height H10 of the top surface 302 of the bottom epitaxial layer 2141.

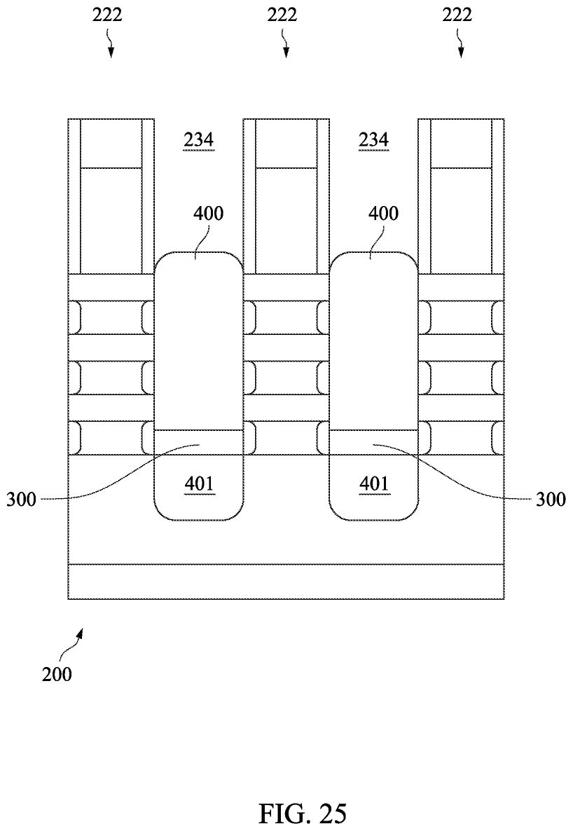

Processing of the structure of FIG. 25 may continue in accordance with the method of FIG. 2. For example, the method may continue, at operation S1110, with forming source/drain regions 400 as described above in relation to FIG. 12.

Through the combination of the laterally-extending (in the Y-direction) isolation layer 300 and the vertically-extending (in the Z-direction) isolation structure 800, devices 200 are provided with reduced parasitic capacitance while still preventing or reducing leakage current under the isolation structure 800 between adjacent active areas. Specifically, the isolation structure 800 may be formed in a shallower trench, resulting in a small parasitic capacitance, and the isolation layer 300 may prevent or reduce leakage current between source/drain regions.

By employing the disclosed process, a process window may be enlarged and device performance and reliability of transistors formed in the adjacent active regions will be enhanced. Those of skill in the art will readily appreciate that the methods and structures described herein may be applied to a variety of other semiconductor devices to advantageously achieve similar benefits from such other devices without departing from the scope of the present disclosure.

Thus, one of the embodiments of the present disclosure describes a method including forming an isolation layer over a semiconductor material; forming source/drain regions over the isolation layer; removing a selected gate structure, wherein removing the selected gate structure forms a trench in the semiconductor material; and forming an isolation structure in the trench.

In certain embodiments of the method, after removing the selected gate structure, a non-selected gate structure remains over the semiconductor material; the non-selected gate structure comprises a stack of vertically spaced-apart nanosheets including a bottom nanosheet having a top surface at a first height over the semiconductor material; the isolation layer has a top surface at a second height over the semiconductor material; and the first height is greater than the second height.

In certain embodiments of the method, after removing the selected gate structure, a non-selected gate structure remains over the semiconductor material; the non-selected gate structure comprises a stack of vertically spaced-apart nanosheets including a top nanosheet having a top surface; the trench has a nadir; the top surface is distanced from the nadir by a vertical distance H; the trench has a width W; and the ratio of H to W is at least 2:1 and at most 5:1.

In certain embodiments of the method, the isolation layer comprises silicon oxide, silicon nitride, or a combination thereof.

In certain embodiments of the method, the isolation layer comprises a plurality of sublayers.

In certain embodiments of the method, the isolation layer has a vertical thickness of less than 6 nanometers (nm).

In certain embodiments of the method, the isolation layer has a band gap of at least 4 eV.

In certain embodiments of the method, the isolation layer has a dielectric constant of less than 7.5.

In certain embodiments of the method, the isolation structure is laterally distanced from a nearest adjacent gate structure by a distance of from 22 to 34 nanometers (nm).

In another embodiment, a semiconductor device is provided and includes a multi-gate structure over a semiconductor substrate; an isolation structure laterally distanced from the multi-gate structure, wherein the isolation structure is located in a trench in the semiconductor substrate; and an isolation layer overlying the semiconductor substrate and extending from the multi-gate structure to the isolation structure.

In exemplary embodiments of the semiconductor device, the multi-gate structure comprises a stack of spaced-apart nanosheets including a bottom nanosheet; the bottom nanosheet has a top surface at a first height over the semiconductor material; the isolation layer has a top surface at a second height over the semiconductor material; and the first height is greater than the second height.

In exemplary embodiments of the semiconductor device, the multi-gate structure comprises a stack of spaced-apart nanosheets including a top nanosheet; the top nanosheet has a top surface at a first height over the semiconductor material; the trench has a nadir; and a vertical distance from the top surface to the nadir is less than 120 nanometers (nm).

In exemplary embodiments of the semiconductor device, the multi-gate structure comprises a stack of spaced-apart nanosheets including a top nanosheet; the top nanosheet has a top surface at a first vertical distance from an upper surface of the semiconductor material; the trench has a nadir, wherein the upper surface of the semiconductor material is located at a second vertical distance from the nadir; the first vertical distance is greater than the second vertical distance.

In exemplary embodiments of the semiconductor device, the semiconductor device includes a source/drain region overlying the isolation layer, the trench has a nadir; the top surface is located at a first vertical distance from the nadir; the source/drain region has a bottom-most surface and an uppermost surface, wherein the uppermost surface is located at a second vertical distance from the bottom-most surface; and the first vertical distance is less than the second vertical distance.

In exemplary embodiments of the semiconductor device, the isolation layer has a vertical thickness of less than 6 nanometers (nm), and the isolation structure is laterally distanced from the multi-gate structure by a distance of from 22 to 34 nanometers (nm).

In another embodiment, a semiconductor device includes a first gate structure and a second gate structure located over a semiconductor material; an isolation structure located between the first gate structure and the second gate structure; a first source/drain region located between the first gate structure and the isolation structure, wherein the first source/drain region is separated from the semiconductor material by a first isolation layer; and a second source/drain region located between the second gate structure and the isolation structure, wherein the second source/drain region is separated from the semiconductor material by a second isolation layer.

In exemplary embodiments of the semiconductor device, the first isolation layer and the second isolation layer comprise a plurality of sublayers, and the first isolation layer and the second isolation layer comprise silicon oxide, silicon nitride, or a combination thereof.

In exemplary embodiments of the semiconductor device, the first isolation layer and the second isolation layer each has a vertical thickness of less than 6 nanometers (nm).

In exemplary embodiments of the semiconductor device, each gate structure contacts the semiconductor material along an interface plane; each gate structure has an uppermost surface located at a first vertical distance over the interface plane; the isolation structure has a nadir; the interface plane is located at a second vertical distance over the nadir; and the first vertical distance is greater than the second vertical distance.

In exemplary embodiments of the semiconductor device, each gate structure contacts the semiconductor material along an interface plane; at the interface plane, each gate structure is distanced from the isolation structure by a lateral distance; at the interface plane, the isolation structure has a lateral width; and the lateral distance is greater than the lateral width.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present.

What is claimed is:

1. A method comprising:
forming an isolation layer over a semiconductor material;
forming source/drain regions over the isolation layer;
removing a selected gate structure, wherein removing the selected gate structure forms a trench in the semiconductor material; and
forming an isolation structure in the trench.

2. The method of claim 1, wherein:
after removing the selected gate structure, a non-selected gate structure remains over the semiconductor material;
the non-selected gate structure comprises a stack of vertically spaced-apart nanosheets including a bottom nanosheet having a top surface at a first height over the semiconductor material;
the isolation layer has a top surface at a second height over the semiconductor material; and
the first height is greater than the second height.

3. The method of claim 1, wherein:
after removing the selected gate structure, a non-selected gate structure remains over the semiconductor material;
the non-selected gate structure comprises a stack of vertically spaced-apart nanosheets including a top nanosheet having a top surface;
the trench has a nadir;
the top surface is distanced from the nadir by a vertical distance H;
the trench has a width W; and
a ratio of H:W is at least 2:1 and at most 5:1.

4. The method of claim 1, wherein the isolation layer comprises silicon oxide, silicon nitride, or a combination thereof.

5. The method of claim 1, wherein the isolation layer comprises a plurality of sublayers.

6. The method of claim 1, wherein the isolation layer has a vertical thickness of less than 6 nanometers (nm).

7. The method of claim 1, wherein the isolation layer has a band gap of at least 4 eV.

8. The method of claim 1, wherein the isolation layer has a dielectric constant of less than 7.5.

9. The method of claim 1, wherein the isolation structure is laterally distanced from a nearest adjacent gate structure by a distance of from 22 to 34 nanometers (nm).

10. A semiconductor device comprising:
a multi-gate structure over a semiconductor substrate;
an isolation structure laterally distanced from the multi-gate structure, wherein the isolation structure is located in a trench in the semiconductor substrate; and
an isolation layer overlying the semiconductor substrate and extending from the multi-gate structure to the isolation structure.

11. The semiconductor device of claim 10, wherein:
the multi-gate structure comprises a stack of spaced-apart nanosheets including a bottom nanosheet;
the bottom nanosheet has a top surface at a first height over the semiconductor substrate;
the isolation layer has a top surface at a second height over the semiconductor substrate; and
the first height is greater than the second height.

12. The semiconductor device of claim 10, wherein:
the multi-gate structure comprises a stack of spaced-apart nanosheets including a top nanosheet;
the top nanosheet has a top surface at a first height over the semiconductor substrate;
the trench has a nadir; and
a vertical distance from the top surface to the nadir is less than 120 nanometers (nm).

13. The semiconductor device of claim 10, wherein:
the multi-gate structure comprises a stack of spaced-apart nanosheets including a top nanosheet;
the top nanosheet has a top surface at a first vertical distance from an upper surface of the semiconductor substrate;
the trench has a nadir;
the upper surface of the semiconductor substrate is located at a second vertical distance from the nadir; and
the first vertical distance is greater than the second vertical distance.

14. The semiconductor device of claim 10, wherein:
the semiconductor device further comprises a source/drain region overlying the isolation layer;
the trench has a nadir;
a top surface of the semiconductor substrate is located at a first vertical distance from the nadir;
the source/drain region has a bottom-most surface and an uppermost surface the uppermost surface is located at a second vertical distance from the bottom-most surface; and
the first vertical distance is less than the second vertical distance.

15. The semiconductor device of claim 10, wherein the isolation layer has a vertical thickness of less than 6 nanometers (nm), and wherein the isolation structure is laterally distanced from the multi-gate structure by a distance of from 22 to 34 nanometers (nm).

16. A semiconductor device comprising:
a first gate structure and a second gate structure located over a semiconductor material;
an isolation structure located between the first gate structure and the second gate structure;
a first source/drain region located between the first gate structure and the isolation structure, wherein the first source/drain region is separated from the semiconductor material by a first isolation layer; and
a second source/drain region located between the second gate structure and the isolation structure, wherein the second source/drain region is separated from the semiconductor material by a second isolation layer.

17. The semiconductor device of claim 16, wherein the first isolation layer and the second isolation layer comprise sublayers, and wherein the first isolation layer and the second isolation layer comprise silicon oxide, silicon nitride, or a combination thereof.

18. The semiconductor device of claim 16, wherein the first isolation layer and the second isolation layer each has a vertical thickness of less than 6 nanometers (nm).

19. The semiconductor device of claim 16, wherein:
each gate structure contacts the semiconductor material along an interface plane;
each gate structure has an uppermost surface located at a first vertical distance over the interface plane;
the isolation structure has a nadir;
the interface plane is located at a second vertical distance over the nadir; and
the first vertical distance is greater than the second vertical distance.

20. The semiconductor device of claim 16, wherein:
each gate structure contacts the semiconductor material along an interface plane;
at the interface plane, each gate structure is distanced from the isolation structure by a lateral distance;
at the interface plane, the isolation structure has a lateral width; and
the lateral distance is greater than the lateral width.
